(19) United States
(12) Patent Application Publication
(10) Pub. No.: US 2022/0192030 A1
(43) Pub. Date: Jun. 16, 2022

(54) CIRCUIT BOARDS HAVING SIDE-MOUNTED COMPONENTS ANS ADDITIVE MANUFACTURINGF METHODS THEREOF

(71) Applicants: Nano Dimension Technologies LTD., Nes Ziona (IL); THE IP LAW FIRM OF GUY LEVI, LLC, Wyckoff, NJ (US)

(72) Inventors: Daniel Sokol, Rishon L'etsion (IL); Aviram Lancovici, Rehovot (IL)

(21) Appl. No.: 17/599,652

(22) PCT Filed: Mar. 30, 2020
(86) PCT No.: PCT/US20/25639

§ 371 Date: Sep. 29, 2021

Related U.S. Application Data
(60) Provisional application No. 62/826,435, filed on Mar. 29, 2019.

(51) Int. Cl. H05K 3/12; B33Y 80/00; H05K 3/00; B33Y 10/00; B29C 64/112; B29C 64/209; B29C 64/393; B33Y 50/02

(52) U.S. Cl. CPC H05K 3/125; B33Y 80/00; H05K 3/0014; B33Y 10/00; B29L 2031/3425; B29C 64/209; B29C 64/393; B33Y 50/02; B29C 64/112

(57) ABSTRACT

The disclosure relates to systems and methods for using additive manufacturing (AM) to fabricate printed circuits having side-mounted components and contacts. More specifically, the disclosure is directed to additive manufacturing methods for fabricating electronic components (AME), for example; printed circuit board (PCB), flexible printed circuit (FPC) and high-density interconnect printed circuit board (HDIPCB) (the PCBs, FPCs, and HDIPCB's together referred to as AMEs, or AME circuits), having conductive contacts and/or components along the Z axis of side walls or facets of the each of the printed AMEs.

### BACKGROUND

The disclosure is directed to systems and methods for using additive manufacturing (AM) to fabricate printed circuits having side-mounted components and contacts. More specifically, the disclosure is directed to additive manufacturing methods for fabricating electronic components (AME), for example; printed circuit board (PCB), flexible printed circuit (FPC) and high-density interconnect printed circuit board (HDIPCB) (the PCBs, FPCs, and HDIPCB's together referred to as AMEs, or AME circuits), having conductive contacts and/or components along the Z axis of side walls or facets of the each of the printed AMEs.

Electronic devices with small form factor are increasingly in demand in all areas of, for example: manufacture, business, consumer goods, military, aeronautics, internet of things, and others. Products having these smaller form factors rely on compact circuits boards with tightly spaced digital and analog circuits placed in close proximity. Increased device complexity combined with strict packaging constraints can lead to a substantial increase in layer count and board thickness of the circuit boards, for example in mobile communication devices. However, in many cases, the mostly reductive methods of fabrication drive the lower end of the form factor capabilities.

The increase in the number of layer as discussed herein, hence the side facets' thickness, with the desired increase in complexity, can create an opportunity to provide heretofore unused and, due to current manufacturing methods, impractical surface for mounting various components, while ensuring reliable connectivity and functionality.

The present disclosure is directed toward overcoming one or more of the above-identified shortcomings by the use of additive manufacturing technologies and systems.

### SUMMARY

Disclosed, in various examples, configurations and implementations, are additive manufacturing methods for fabricating electronic components (AME), for example; printed circuit board (PCB), flexible printed circuit (FPC) and high-density interconnect printed circuit board (HDIPCB) having conductive contacts and/or components along the Z axis of side walls or facets of the each of the printed AMEs.

In another configuration, the plurality of side-mounted contacts are orthogonally separated, and are configured to operate as orthogonally isolated elements for an electrically small antenna (ESA).

In yet another implementation, provided herein is a method for fabricating at least one of: a printed circuit board (PCB), a flexible printed circuit (FPC), and a high-density interconnect printed circuit board (HDIPCB), each comprising at least one of: a side-mounted component, and a plurality of side-mounted contacts using additive manufacturing, the method comprising: providing an ink jet printing system having: a first print head adapted to dispense a dielectric ink; a second print head adapted to dispense a conductive ink; a conveyor, operably coupled to the first and second print heads, configured to convey a substrate to each print heads; and a computer aided manufacturing (“CAM”) module, in communication with each of the first, and second print heads, the CAM further comprising a central processing module (CPM) including at least one processor in communication with a non-transitory computer readable storage medium configured to store instructions that, when executed by the at least one processor cause the CAM to control the ink-jet printing system, by carrying out steps that comprise: receiving a 3D visualization file representing the at least one of: PCB, FPC, and HDIPCB each comprising at least one side-mounted component; and generating a file library having a plurality of files, each file representing a substantially 2D layer for printing the at least one of: PCB, FPC, and HDIPCB each comprising at least one side-mounted component, and a metafile representing at least the printing order; providing the dielectric inkjet ink composition, and the conductive inkjet ink composition; using the CAM module, obtaining the first layer file; using the first print head, forming the pattern corresponding to the dielectric inkjet ink; curing the pattern corresponding to the dielectric inkjet ink; using the second print head, forming the pattern corresponding to the conductive ink, the pattern further corresponding to the substantially 2D layer for printing of the at least one of: PCB, FPC, and HDIPCB each comprising at least one side-mounted component; sintering the pattern corresponding to the conductive inkjet ink; using the CAM module, obtaining from the library a subsequent file representative of a subsequent layer for printing the at least one of: PCB, FPC, and HDIPCB each comprising at least one side-mounted component; the subsequent file comprising printing instructions for a pattern representative of at least one of: the dielectric ink, and the conductive ink; repeating the steps of: using the first print head, forming the pattern corresponding to the dielectric ink, to the step of using the CAM module, obtaining from the 2D file library the subsequent, substantially 2D layer, wherein upon printing the final layer, the at least one of: PCB, FPC, and HDIPCB each comprising at least one side-mounted component comprises a plurality of conductive side mounted contacts operable to mount at least one component; and optionally coupling at least one component to the plurality of printed side contacts.

It is noted, that the library comprises computer aided design (CAD)-generated layout of traces and dielectric insulating (DI) material, and the metafile required for their retrieval, including for example, labels, printing chronological order and other information needed for using in the additive manufacturing systems used.

In yet another exemplary implementation, provided herein is at least one of: a printed circuit board (PCB), a flexible printed circuit (FPC), and a high-density interconnect printed circuit board (HDIPCB), each comprising a plurality of side-mounted contact pads, each contact pad sized and configured to operably couple to a chip package.

In an exemplary implementation, the plurality of side-mounted contacts are sized and configured to operate as a portion of a socket, sized and configured to operably to a complementary socket of a separate printed circuit board (PCB), flexible printed circuit (FPC), and high-density interconnect printed circuit board (HDIPCB).

These and other features of the systems, and methods for AME circuits having side-mounted components and contacts, will become apparent from the following detailed description when read in conjunction with the figures and examples, which are exemplary, not limiting.

### BRIEF DESCRIPTION OF THE FIGURES

For a better understanding of the AME circuits having side-mounted components and contacts, their fabrication methods and compositions, with regard to the exemplary implementations thereof, reference is made to the accompanying examples and figures, in which:

FIG. 1, is an isometric schematic view of a printed circuit fabricated using the disclosed methods;

FIG. 2, is an isometric schematic view of a complementary AME circuit to the AME schematic illustrated in FIG. 1, fabricated using the disclosed methods;

FIG. 3, is a schematic of an electrically small antenna fabricated using the disclosed methods with an orthogonally separated antenna elements;

FIG. 4A-4C are examples of printed circuit boards fabricated using the disclosed methods;

FIG. 5 is a schematic illustration of a socket protrusion sized and configured to operably couple to a complementary socket in another printed circuit, the socket fabricated using the disclosed methods and systems;

FIG. 6, is a schematic illustrating the peripherally extending structures encasing the conductive side-mounted contacts, protrusions and coupling elements illustrated in FIGS. 1, 2, and 5;

FIG. 7, depicts an AME circuit fabricated using the methods described, with a plurality of side contacts, configured to be engaged in a PLCC socket, like the one shown in FIG. 8.

### DETAILED DESCRIPTION

Provided herein are examples, configurations and implementations of systems and methods for fabricating printed circuits having side-mounted components and contacts. More specifically, provided herein are examples, configurations and implementations of additive manufacturing methods for fabricating at least one of printed circuit board (PCB), flexible printed circuit (FPC) and high-density interconnect printed circuit board (HDIPCB) together referred to as indicated above, as AMEs, or AME circuits; having conductive contacts and/or components along the Z axis of each of the printed circuits outer facets (in other words, side-mounted).

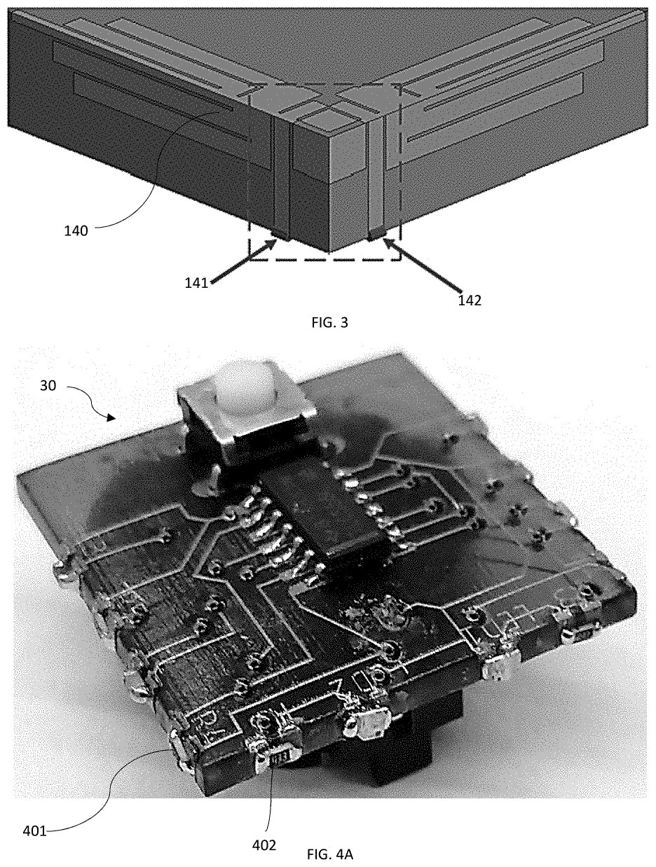

The systems and methods described herein provide exposed conductive traces on the side border facets of the printed boards. The conductive traces and contacts can be formed side-by-side, and/or one above the other. Each of the side contacts shall be connected to a signal trace inside the board, in other words, be connected to any printed board layer and at any height. Similarly the vertical (or horizontal (see e.g., FIG. 3) conductive contacts or traces, can be formed in any of the exposed surface of an additive manufacturing structure where the conductive contacts or traces material is distinctively different than the build material (e.g., the dielectric insulating material), thus creating probes, connectors, ports, etc.

In standard additive manufacturing techniques where metal traces and dielectric are used, and more specifically in the case of inkjet printing, the vertical metal component can be printed in a cavity, drill, or bore that surrounds the entire metal structure, such as (filled, or plated) vias in PCB. In an exemplary implementation the metal, conductive content can be exposed, typically toward the periphery of the host material, a typically non-conductive material.

In certain examples, the side contacts' structure is first created using conventional methods, which enclose the entire vertical conductive structure to be exposed and the excess material is removed (for example, by either slicing or milling it). In other configurations, the system may comprise a print head equipped with support material that can be removed by washing.

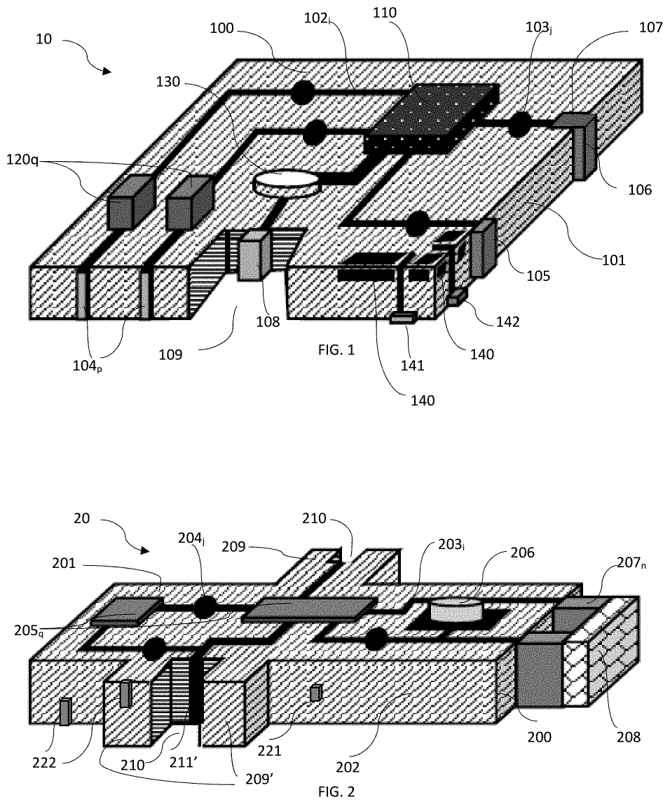

Here, the systems, methods and compositions described herein can be used to form/fabricate AMEs described, comprising side-mounted conductive elements (traces, contacts, sockets, orthogonally separated antennae elements e.g.) optionally coupled to components, utilizing a combination of print heads with conductive and dielectric ink compositions in a single, continuous additive manufacturing (AM) process, using for example, an inkjet printing device, or using several passes. Using the systems, methods and compositions described herein, a thermoset resin material can be used to form the insulating and/or dielectric portion of the printed boards (see e.g., 100 FIG. 1). This printed dielectric inkjet ink (DI) material is printed in optimized 3D pattern including accurate depressions and protrusions shaped to form the hollowed cylinders or other vertically hollowed structures (see e.g., 603, 605, FIG. 6) extending peripherally beyond the side facet (101, 202 FIGS. 1 and 2 respectively).

While reference is made to inkjet inks, other additive manufacturing methods (also known as rapid prototyping, rapid manufacturing, aerosol printing, Laser Induced Forward Transfer (LIFT) and 3D printing), are also contemplated in the implementation of the disclosed methods. In the exemplary implementation, the AME circuits described, comprising side-mounted contacts, traces, ports and the like, can likewise be fabricated by a selective laser sintering (SLS) process, direct metal laser sintering (DMLS), electron beam melting (EBM), selective heat sintering (SHS), or stereolithography (SLA). The AME circuits described, comprising side-mounted contacts, traces, ports and the like may be fabricated from any suitable additive manufacturing material, such as metal powder(s) (e.g., cobalt chrome, steels, aluminum, titanium and/or nickel alloys, gold), gas atomized metal powder(s), thermoplastic powder(s) (e.g., polylactic acid (PLA), acrylonitrile butadiene styrene (ABS), and/or high-density polyethylene (HDPE)), photopolymer resin(s) (e.g., UV-curable photopolymers such as, for example PMMA), thermoset resin(s), thermoplastic resin(s), or any other suitable material that enables the functionality as described herein.

The systems used can typically comprise several sub-systems and modules. These can be, for example: additional conductive and dielectric print-heads, a mechanical sub-system to control the movement of the print heads, the substrate (or chuck) its heating and conveyor motions; the ink composition injection systems; the curing/sintering sub-systems; a computerized sub-system with at least one processor or CPU that is configured to control the process and generates the appropriate printing instructions, a component placement system such as automated robotic arm, a material removal sub-system, (such as Laser applicator, a lathe, a knife and the like), a machine vision system, and a command and control system to control the 3D printing.

Accordingly and in an exemplary implementation, provided herein is a method for fabricating at least one of: a printed circuit board (PCB), a flexible printed circuit (FPC), and a high-density interconnect printed circuit board (HDIPCB), each comprising at least one of: a side-mounted component, and a plurality of side-mounted contacts using additive manufacturing, the method comprising: providing an ink jet printing system having: a first print head adapted to dispense a dielectric ink; a second print head adapted to dispense a conductive ink; a conveyor, operably coupled to the first and second print heads, configured to convey a substrate to each print heads; and a computer aided manufacturing (“CAM”) module, in communication with each of the first, and second print heads, the CAM further comprising a central processing module (CPM) including at least one processor in communication with a non-transitory computer readable storage medium configured to store instructions that, when executed by the at least one processor cause the CAM to control the ink-jet printing system, by carrying out steps that comprise: receiving a 3D visualization file representing the at least one of: PCB, FPC, and HDIPCB each comprising at least one side-mounted component; and generating a file library having a plurality of files, each file representing a substantially 2D layer for printing the at least one of: PCB, FPC, and HDIPCB each comprising at least one side-mounted component, and a metafile representing at least the printing order; providing the dielectric inkjet ink composition, and the conductive inkjet ink composition; using the CAM module, obtaining the first layer file; using the first print head, forming the pattern corresponding to the dielectric inkjet ink; curing the pattern corresponding to the dielectric inkjet ink; using the second print head, forming the pattern corresponding to the conductive ink, the pattern further corresponding to the substantially 2D layer for printing of the at least one of: PCB, FPC, and HDIPCB each comprising at least one side-mounted component; sintering the pattern corresponding to the conductive inkjet ink; using the CAM module, obtaining from the library a subsequent file representative of a subsequent layer for printing the at least one of: PCB, FPC, and HDIPCB each comprising at least one side-mounted component; the subsequent file comprising printing instructions for a pattern representative of at least one of: the dielectric ink, and the conductive ink; repeating the steps of: using the first print head, forming the pattern corresponding to the dielectric ink, to the step of using the CAM module, obtaining from the 2D file library the subsequent, substantially 2D layer, wherein upon printing the final layer, the at least one of: PCB, FPC, and HDIPCB each comprising at least one side-mounted component comprises a plurality of conductive side mounted contacts operable to mount at least one component; and optionally coupling at least one component to the plurality of printed side contacts.

Additionally, or alternatively, the methods provided for fabricating side-mounted components onto AMEs disclosed herein further comprise: using the first print head, printing a pattern corresponding to a via, the pattern corresponding to the via extending peripherally from the facet of at least one of the PCB, FCP and HDIPCB; curing the pattern corresponding to the via; using the second print head, printing a pattern corresponding to a conductive portion of the via; sintering the pattern corresponding to the conductive portion of the via; and removing at least a portion of a vertical portion of the cured dielectric pattern extending peripherally, thereby exposing a portion of the conductive ink, wherein the step of removing at least a portion of a vertical portion of the cured dielectric pattern extending peripherally, comprises using at least one of: a laser applicator, a lathe, a knife, and a resin removing means, thereby exposing the conductive contact.

The use of the term “module” does not imply that the components or functionality described or claimed as part of the module are all configured in a (single) common package. Indeed, any or all of the various components of a module, whether control logic or other components, can be combined in a single package or separately maintained and can further be distributed in multiple groupings or packages or across multiple (remote) locations and devices. Furthermore, in certain exemplary implementations, the term “module” refers to a monolithic or distributed hardware unit(s).

In an exemplary implementation, the term “dispense”, in the context of the first print-head is used to designate the device from which the inkjet ink drops are dispensed. The dispenser can be, for example an apparatus for dispensing small quantities of liquid including micro-valves, piezoelectric dispensers, continuous-jet print-heads, boiling (bubble-jet) dispensers, and others affecting the temperature and properties of the fluid flowing through the dispenser.

The set of executable instructions are further configured, when executed to cause the processor to: using the 3D visualization file, generate a 2D file library of a plurality of subsequent layers' files each subsequent file represents a substantially two dimensional (2D) subsequent layer for printing a subsequent portion of the at least one of PCB, FPC and HDIPCB comprising the at least one of: a side-mounted component, and a plurality of side-mounted contacts, wherein each subsequent layer file is indexed by printing order.

In the context of the disclosure, the term “2D file library” refers to a given set of files that when assembled and printed together define a single AME with side-mounted components' contacts, or a plurality of AME with side-mounted components' contacts, used for a given purpose. Furthermore, the term “2D file library” can also be used to refer to a set of 2D files or any other raster graphic file format (the representation of images as a collection of pixels, generally in the form of a rectangular grid, e.g., BMP, PNG, TIFF, GIF), capable of being indexed, searched, and reassembled, to provide the sequential structural layers of a given AME circuit, whether the search is for the AME with side-mounted components' contacts as a whole, or a given specific 2D layer within the AME.

Moreover, each file in the 2D file library, has an associated metadata defining at least the print order of the layer as well as other instructions for the printing system, such as printing speed (m/sec), order of the CI vs. DI and the like. In the context of the disclosure, “metadata” is used herein to generally refer to data that describes other data, such as data that describes the CI and/or DI pattern to be printed. It will be understood, however, that the term “data” as used herein can refer to either data or metadata.

Then, using the library, retrieve a 2D file for printing and generate for example (depending e.g., on the 2D layer file's metadata), a conductive ink pattern comprising the conductive portion of each of the 2D layer files for printing the conductive portion of the retrieved layer of the AME with side-mounted components' contacts, then generate the ink pattern corresponding to the dielectric ink portion of each of the 2D layer files for printing a dielectric portion of the (same or different) layer of the AME with side-mounted components' contacts, wherein the CAM module is configured and operable to control each of the first and the second print heads, thereby obtaining the 2D layer. Then depending on the printing order configured in the 2D file's metadata, using the first print head, forming the pattern corresponding to the dielectric ink in the retrieved 2D layer file, and curing the DI pattern. Then using the second print head, forming the pattern corresponding to the conductive ink in the retrieved 2D layer file, and sintering the pattern corresponding to the conductive ink, thereby obtaining a single, substantially 2D layer of the AME with side-mounted components' contacts. In the context of the disclosure, substantially 2D layer means a single layer forming a film of a thickness of between about 10 μm and about 55 μm, for example, between about 15 μm and about 45 μm, or between about 17 μm and about 35 μm.

Accordingly and in an exemplary implementation, the methods implemented using the systems and compositions provided to form/fabricate at least one AME, comprising side-mounted conductive elements (traces, pads, contacts, sockets e.g.) optionally coupled to components, further comprise, prior to the step of optionally coupling the at least one component (for example by automatically placing a chip and soldering those into the now exposed side contact 207n, FIG. 2), or similarly: using the CAM module, accessing the library; obtaining a generated file representing 2D subsequent layer of the PCB; and repeating the steps for forming the subsequent layer.

The term “chip” refers to a packaged, singulated, integrated circuit (IC) device. The singulated IC can be packaged in a housing or another structure (a “chip package”) that, for example, facilitates the coupling of the singulated IC to the AME circuit. Accordingly and in the context of the disclosure, the term “chip package” may particularly denote a housing that singulated IC devices (interchangeable with “chips”), come in for plugging into (socket mount) or soldering onto (surface mount) a circuit board such as the AME circuits), thus creating a side mounting site (the “side contact” for a chip. In electronics, the term chip package or chip carrier may denote the material added around a component or integrated circuit to allow it to be handled without damage and incorporated into a circuit. Furthermore, the chip or chip package used in conjunction with the systems, methods and compositions described herein can be Quad Flat Pack (QFP) package, a Thin Small Outline Package (TSOP), a Small Outline Integrated Circuit (SOIC) package, a Small Outline J-Lead (SOJ) package, a Plastic Leaded Chip Carrier (PLCC) package, a Wafer Level Chip Scale Package (WLCSP), a Mold Array Process-Ball Grid Array (MAPBGA) package, a Ball-Grid Array (BGA), a Quad Flat No-Lead (QFN) package, a Land Grid Array (LGA) package, a passive component, or a combination comprising two or more of the foregoing.

The CAM module can therefore comprise: a 2D file library storing the files converted from the 3D visualization files of the AME with side-mounted components' contacts. The term “library, as used herein, refers to the collection of 2D layer files derived from the 3D visualization file, containing the information necessary to print each conductive and dielectric pattern, which is accessible and used by the data collection application, which can be executed by the computer-readable media. The CAM further comprises a processor in communication with the library; a memory device storing a set of operational instructions for execution by the processor; a micromechanical inkjet print head or heads in communication with the processor and with the library; and a print head (or, heads') interface circuit in communication with the 2D file library, the memory and the micromechanical inkjet print head or heads, the 2D file library configured to provide printer operation parameters specific to a functional layer.

In certain configurations, the systems provided herein further comprise a robotic arm equipped with a knife, a rotating bit, a laser source or other DI removal means in communication with the CAM module and under the control of the CAM module, configured to remove excess material from the structures encasing the conductive material forming the side-mounted contacts thus exposing the contacts, ports, traces and other conductive structures. In certain alternative, or additional configurations, the systems provided herein further comprise a third print head, configured to dispense a support ink.

Using the additional support ink head, the method to form/fabricate at least one AME, comprising side-mounted conductive elements (traces, contacts, sockets, orthogonally separated antennae elements e.g.) optionally coupled to components can further comprise providing a support ink composition; either subsequent, sequentially or simultaneously to the step of using the first print head, the second print head, or any other functional print head (and any permutation thereof). Using the support ink print head, forming a predetermined pattern corresponding to the support representation generated by the CAM module from the 3D visualization file, and represented as a pattern in the first (and subsequent), substantially 2D layer(s) of the composite component for printing, wherein that 2D pattern correspond to the structure comprising the conductive material extending beyond the periphery of the printed board, the support ink being sized and configured to be removed. The predetermined pattern corresponding to the support representation can then be further treated (e.g., cured, cooled, crosslinked and the like), to functionalize the pattern as support as described hereinabove in the 2D layers of the side-mounted contact, or when used, for the dielectric portion defining the via(s). The process of depositing the support can be repeated thereafter for every sequential layer as needed.

In an exemplary implementation, the first conductive inkjet ink can contain silver, while an additional inkjet ink can contain copper, thus allowing printing of integral, built-in ports, or connectors having silver electrodes, with copper connection terminals (see e.g., 211′, FIG. 2). Other conductive materials that can be used additionally or alternatively in the conductive print head(s), can be Nickel, Gold, Aluminum, Platinum and the like.

The term “forming” (and its variants “formed”, etc.) refers in an certain examples, to pumping, injecting, pouring, releasing, displacing, spotting, circulating, or otherwise placing a fluid or material (e.g., the conducting ink) in contact with another material (e.g., the substrate, the resin or another layer) using any suitable manner known in the art.

Curing the insulating and/or dielectric layer or pattern deposited by the appropriate print head as described herein, can be achieved by, for example, heating, photopolymerizing, drying, depositing plasma, annealing, facilitating redox reaction, irradiation by ultraviolet beam or a combination comprising one or more of the foregoing. Curing does not need to be carried out with a single process and can involve several processes either simultaneously or sequentially, (e.g., drying and heating and depositing crosslinking agent with an additional print head)

Furthermore, and in another exemplary implementation, crosslinking refers to joining moieties together by covalent bonding using a crosslinking agent, i.e., forming a linking group, or by the radical polymerization of monomers such as, but not limited to methacrylates, methacrylamides, acrylates, or acrylamides. In some configurations, the linking groups are grown to the end of the polymer arms.

Therefore, in an exemplary implementation, the vinyl constituents are monomers comonomers, and/or oligomers selected from the group comprising a multi-functional acrylate, their carbonate copolymers, their urethane copolymers, or a composition of monomers and/or oligomers comprising the foregoing. Thus, the multifunctional acrylate is 1,2-ethanediol diacrylate, 1,3-propanediol diacrylate, 1,4-butanediol diacrylate, 1,6-hexanediol diacrylate, dipropylene glycol diacrylate, neopentyl glycol diacrylate, ethoxylated neopentyl glycol diacrylate, propoxylated neopentyl glycol diacrylate, tripropylene glycol diacrylate, bisphenol-A-diglycidyl ether diacrylate, hydroxypivalic acid neopentanediol diacrylate, ethoxylated bisphenol-A-diglycidyl ether diacrylate, polyethylene glycol diacrylate, trimethylolpropane triacrylate, ethoxylated trimethylolpropane triacrylate, propoxylated trimethylolpropane triacrylate, propoxylated glycerol triacrylate, tris(2-acryloyloxyethyl)isocyanurate, pentaerythritol triacrylate, ethoxylated pentaerythritol triacrylate, pentaerythritol tetraacrylate, ethoxylated pentaerythritol tetraacrylate, ditrimethylolpropane tetraacrylate, dipentaerythritol pentaacrylate and dipentaerythritol hexaacrylate or a multifunctional acrylate composition comprising one or more of the foregoing

In an exemplary implementation, the term “copolymer” means a polymer derived from two or more monomers (including terpolymers, tetrapolymers, etc.), and the term “polymer” refers to any carbon-containing compound having repeat units from one or more different monomers.

Other functional heads may be located before, between or after the inkjet ink print heads used in the systems for implementing the methods described herein. These may include a source of electromagnetic radiation configured to emit electromagnetic radiation at a predetermined wavelength (X), for example, between 190 nm and about 400 nm, e.g. 395 nm which in an exemplary implementation, can be used to accelerate and/or modulate and/or facilitate a photopolymerizable insulating and/or dielectric that can be used in conjunction with metal nanoparticles dispersion used in the conductive ink. Other functional heads can be heating elements, additional printing heads with various inks (e.g., support, pre-soldering connective ink, label printing of various components for example capacitors, transistors and the like) and a combination of the foregoing.

Other similar functional steps (and therefore the support systems for affecting these steps) may be taken before or after each of the DI or metallic conducting inkjet ink print heads (e.g., for sintering the conducting layer). These steps may include (but not limited to): a heating step (affected by a heating element, or hot air); photobleaching (of a photoresist mask support pattern), photocuring, or exposure to any other appropriate actininc radiation source (using e.g., a UV light source); drying (e.g., using vacuum region, or heating element); (reactive) plasma deposition (e.g., using pressurized plasma gun and a plasma beam controller); cross linking such as by using cationic initiator e.g. [4-[(2-hydroxytetradecyl)-oxyl]-phenyl]-phenyliodonium hexafluoro antimonate to a flexible resin polymer solutions or flexible conductive resin solutions; prior to coating; annealing, or facilitating redox reactions and their combination regardless of the order in which these processes are utilized. In certain exemplary implementation, a laser (for example, selective laser sintering/melting, direct laser sintering/melting), or electron-beam melting can be used on the rigid resin, and/or the flexible portion. It should be noted, that sintering of the conducting portions can take place even under circumstances whereby the conducting portions are printed on top of a rigid resinous portion of the printed circuit boards having side-mounted components and contacts described herein component.

Formulating the conducting ink composition may take into account the requirements, if any, imposed by the deposition tool (e.g., in terms of viscosity and surface tension of the composition) and the deposition surface characteristics (e.g., hydrophilic or hydrophobic, and the interfacial energy of the substrate or the support material (e.g., glass) if used), or the substrate layer on which consecutive layers are deposited. For example, the viscosity of either the conducting inkjet ink and/or the DI (measured at the printing temperature ° C.) can be, for example, not lower than about 5 cP, e.g., not lower than about 8 cP, or not lower than about 10 cP, and not higher than about 30 cP, e.g., not higher than about 20 cP, or not higher than about 15 cP. The conducting ink, can each be configured (e.g., formulated) to have a dynamic surface tension (referring to a surface tension when an ink-jet ink droplet is formed at the print-head aperture) of between about 25 mN/m and about 35 mN/m, for example between about 29 mN/m and about 31 mN/m measured by maximum bubble pressure tensiometry at a surface age of 50 ms and at 25° C. The dynamic surface tension can be formulated to provide a contact angle with the peelable substrate, the support material, the resin layer(s), or their combination, of between about 100° and about 165°.

In an exemplary implementation, the term “chuck” is intended to mean a mechanism for supporting, holding, or retaining a substrate or a workpiece. The chuck may include one or more pieces. In one configuration, the chuck may include a combination of a stage and an insert, a platform, be jacketed or otherwise be configured for heating and/or cooling and have another similar component, or any combination thereof.

In an exemplary implementation, the ink-jet ink compositions, systems and methods allowing for a direct, continuous or semi-continuous ink-jet printing to form/fabricate at least one AME, comprising side-mounted conductive elements (traces, contacts, sockets, antennae elements e.g.) optionally coupled to components can be patterned by expelling droplets of the liquid ink-jet ink provided herein from an orifice one-at-a-time, as the print-head (or the substrate) is maneuvered, for example in two (X-Y) (it should be understood that the print head can also move in the Z axis) dimensions at a predetermined distance above the removable substrate or any subsequent layer. The height of the print head can be changed with the number of layers, maintaining for example a fixed distance. Each droplet can be configured to take a predetermined trajectory to the substrate on command by, for example a pressure impulse, via a deformable piezo-crystal in an certain configurations, from within a well operably coupled to the orifice. The printing of the first inkjet metallic ink can be additive and can accommodate a greater number of layers. The ink-jet print heads provided used in the methods described herein can provide a minimum layer film thickness equal to or less than about 0.3 μm-10,000 μm

The conveyor maneuvering among the various print heads used in the methods described and implementable in the systems described can be configured to move at a velocity of between about 5 mm/sec and about 1000 mm/sec. The velocity of the e.g., chuck can depend, for example, on: the desired throughput, the number of print heads used in the process, the number and thickness of layers of the printed circuit boards having side-mounted components and contacts described herein printed, the curing time of the ink, the evaporation rate of the ink solvents, the distance between the print head(s) containing the first ink-jet conducting ink of the metal particles or metallic polymer paste and the second print head comprising the second, thermoset resin and board forming inkjet ink, and the like or a combination of factors comprising one or more of the foregoing.

In an exemplary implementation, the volume of each droplet of the metallic (or metallic) ink, and/or the second, resin ink, can range from 0.5 to 300 picoLiter (pL), for example 1-4 pL and depended on the strength of the driving pulse and the properties of the ink. The waveform to expel a single droplet can be a 10V to about 70 V pulse, or about 16V to about 20V, and can be expelled at frequencies between about 2 kHz and about 500 kHz.

The 3D visualization file representing the printed circuit boards having side-mounted components and contacts used for the fabrication, can be: an ODB, an ODB++, an.asm, an STL, an IGES, a DXF, a DMIS, NC, a STEP, a Catia, a SolidWorks, a Autocad, a ProE, a 3D Studio, a Gerber, an EXCELLON file, a Rhino, a Altium, an Orcad, an or a file comprising one or more of the foregoing; and wherein file that represents at least one, substantially 2D layer (and uploaded to the library) can be, for example, a JPEG, a GIF, a TIFF, a BMP, a PDF file, or a combination comprising one or more of the foregoing.

In certain configurations, the CAM module further comprises a computer program product to form/fabricate at least one AME, comprising side-mounted conductive elements (traces, contacts, sockets, orthogonally separated antennae elements e.g.) optionally coupled to components, for example, an electronic component, machine part, a connector, another AME circuit and the like. The printed component can comprise both discrete metallic (conductive) components and resinous (insulating and/or dielectric) components that are each and both being printed optionally simultaneously or sequentially and continuously, on either a rigid portion or a flexible portion of the AMEs. The term “continuous” and its variants are intended to mean printing in a substantially unbroken process. In another exemplary implementation, continuous refers to a layer, member, or structure in which no significant breaks in the layer, member, or structure lie along its length.

The computer controlling the printing process described herein can comprise: a computer readable storage medium having computer readable program code embodied therewith, the computer readable program code when executed by a processor in a digital computing device causes a three-dimensional inkjet printing unit to perform the steps of: pre-process Computer-Aided Design/Computer-Aided Manufacturing (CAD/CAM) generated information (e.g., the 3D visualization file), associated with the AME circuits described, comprising side-mounted contacts, traces, ports and the like to be fabricated, thereby creating a library of a plurality of 2D files (in other words, the file that represents at least one, substantially 2D layer for printing the AME); direct a stream of droplets of a metallic material from a second inkjet print head of the three-dimensional inkjet printing unit at a surface of a substrate; direct a stream of droplets of a DI resin material from a first inkjet print head at the surface of the substrate; alternatively or additionally direct a stream of droplets material from another inkjet print head (e.g., the support ink); move the substrate relative to the inkjet heads in an x-y plane of the substrate, wherein the step of moving the substrate relative to the inkjet heads in the x-y plane of the substrate, for each of a plurality of layers (and/or the patterns of conductive or DI inkjet inks within each layer), is performed in a layer-by-layer fabrication of the AME circuits described.

In addition, the computer program, can comprise program code means for carrying out the steps of the methods described herein, as well as a computer program product comprising program code means stored on a medium that can be read by a computer. Memory device(s) as used in the methods described herein can be any of various types of non-volatile memory storage devices or storage devices (in other words, memory devices that do not lose the information thereon in the absence of power). The term “memory device” is intended to encompass an installation medium, e.g., a CD-ROM, floppy disks, or tape device or a non-volatile memory such as a magnetic media, e.g., a hard drive, SATA, SSD, optical storage, or ROM, EPROM, FLASH, etc. The memory device may comprise other types of memory as well, or combinations thereof. In addition, the memory medium may be located in a first computer in which the programs are executed (e.g., the 3D inkjet printer provided), and/or may be located in a second different computer which connects to the first computer over a network, such as the Internet. In the latter instance, the second computer may further provide program instructions to the first computer for execution. The term “memory device” can also include two or more memory devices which may reside in different locations, e.g., in different computers that are connected over a network. Accordingly, for example, the bitmap library can reside on a memory device that is remote from the CAM module coupled to the 3D inkjet printer provided, and be accessible by the 3D inkjet printer provided (for example, by a wide area network).

Unless specifically stated otherwise, as apparent from the following discussions, it is appreciated that throughout the specification discussions utilizing terms such as “processing,” “loading,” “in communication,” “detecting,” “calculating,” “determining”, “analyzing,” or the like, refer to the action and/or processes of a computer or computing system, or similar electronic computing device, that manipulate and/or transform data represented as physical, such as a transistor architecture into other data similarly represented as physical structural (in other words, resin or metal/metallic) layers.

The Computer-Aided Design/Computer-Aided Manufacturing (CAD/CAM) generated information associated with the PCB having side-mounted contacts and/or components described herein to be fabricated, which is used in the methods, programs and libraries can be based on converted CAD/CAM data packages can be, for example, IGES, DXF, DWG, DMIS, NC files, GERBER® files, EXCELLON®, STL, EPRT files, an ODB, an ODB++, an.asm, an STL, an IGES, a STEP, a Catia, a SolidWorks, a Autocad, a ProE, a 3D Studio, a Gerber, a Rhino a Altium, an Orcad, an Eagle file or a package comprising one or more of the foregoing. Additionally, attributes attached to the graphics objects transfer the meta-information needed for fabrication and can precisely define the PCBs. Accordingly and in an exemplary implementation, using pre-processing algorithm, GERBER®, EXCELLON®, DWG, DXF, STL, EPRT ASM, and the like as described herein, are converted to 2D files.

The plurality of AMEs with side-mounted contacts fabricated using the methods described herein, can be partially embedded (and hence, partially exposed) in the at least one of PCB, FPC and HDIPCB. As illustrated in FIG. 6, element 604′ is partially embedded within the dielectric material (or “build”) and can be printed directly with the exposed conductive ink extending beyond the peripheral facet 602 of the printed board 600. This can be achieved by designing a via (at least one of a filled through hole via, blind via, and buried via), with at least a portion of the via extending beyond the peripheral facet 602 (or side wall) of printed board 600. Additionally, or alternatively, when implemented, upon removal of the excess material (603, 603′) along line 6.1 (see e.g., FIG. 6), the remaining conductive material 604 is partially embedded (in other words, partially exposed to facet 602). Conversely, the design in the 3D visualization file, for example the Excellon file, can be projected or rasterized to a 2D layer file, defining, when fully fabricated, shaped structure 606, that can be used, for example for coupling an integrated circuit, or with another contact, (see e.g., 207ₙ) as a coupling base for a chip package. Also, and similarly to the via fabrication, when implemented, upon removal of excess material 605, configured to encase (encapsulate) conductive material 606′ (see e.g., FIG. 6), the remaining conductive material 606′ extends peripherally to facet 602,

Moreover, the contacts, sockets, orthogonally separated conductive elements and the like fabricated using the methods described herein can be coupled to traces at any layer, or combination of layers, thus acting as ports and points of contact specific for an internal signal layer. In an exemplary implementation, the plurality of side-mounted contacts are orthogonally separated and orthogonally isolated, thus the orthogonally separated contact can be sized and configured to operate (in other words, being operable) as orthogonally isolated elements for an electrically small antenna (ESA, see e.g., FIG. 3). As used herein, orthogonal separation is used to denote that the contacts are protruding peripherally from the printed circuit such that the protrusions are normal (perpendicular) to each other. As illustrated in FIG. 1, the orthogonally separated and isolated contacts can be used as ports 141, 142, for electrically small antenna (ESA) 140. In an exemplary implementation, the term “electrically small antenna” (ESA), refers to an antenna whereby the largest dimension of the antenna is no more than one-tenth of a wavelength. Thus, a dipole with a length of λ/10, a loop with a diameter of λ/10, or a patch with a diagonal dimension of λ/10 would be considered electrically small. As illustrated in FIG. 1, using the additive manufacturing methods provided herein, it is possible to integrally fabricate into the printed board, a dual port diversity antenna by printing two antennas extending orthogonally thereby ameliorating multipath interference, in order to increase the quality and reliability of wireless communications. This is especially valuable in wireless connections using master multiple input, multiple output (MIMO) communication protocol, such as in 4G, and 5G networks. The orthogonal separation and isolation allows in certain configurations to maintain the spatial separation necessary for exploiting multipath signal propagation.

Further and as illustrated in FIGS. 1, 2, 4 and 5, the plurality of side-mounted contacts fabricated using the methods described herein (see e.g., FIG. 6), are operable as a portion of a socket, wherein, the socket can form a tongue-in-groove (and/or other topological coupling of complementary surfaces) coupling to at the AME with side-mounted components' contacts. Accordingly, for example, using the fabrication methods described herein for forming side-mounted contacts, it is possible to operably couple two or more AMEs with side-mounted components' contacts at various angles relative to each other.

A more complete understanding of the components, processes, assemblies, and devices disclosed herein can be obtained by reference to the accompanying drawings. These figures (also referred to herein as “FIG.s”) are merely schematic representations (e.g., illustrations) based on convenience and the ease of demonstrating the present disclosure, and are, therefore, not intended to indicate relative size and dimensions of the devices or components thereof and/or to define or limit the scope of the exemplary implementations. Although specific terms are used in the following description for the sake of clarity, these terms are intended to refer only to the particular structure of the exemplary configurations selected for illustration in the drawings, and are not intended to define or limit the scope of the disclosure. In the drawings and the following description below, it is to be understood that like numeric designations refer to components of like function and/or composition and/or structure.

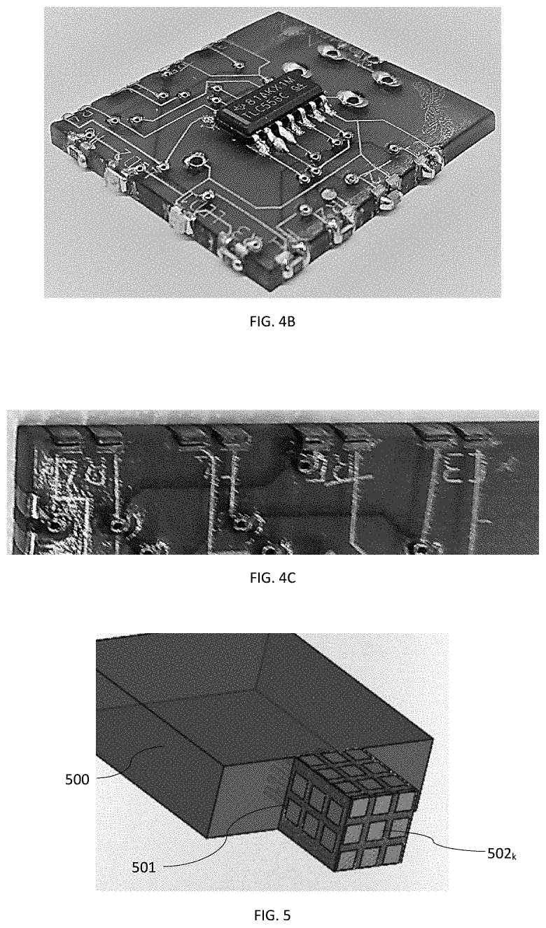

Turning to FIGS. 1-2, and 6 illustrating in FIG. 1, a perspective view of AME (used interchangeably with FPC and HDIPCB) 10. AME 10 having upper surface 100, and side walls, or periphery facet(s) 101. Side-mounted contacts 104p, 105 and 106 were formed (see e.g., FIGS. 4A-4C) and connected on the active top layer using traces 102i, with an examples of vias 103j some of which are through hole vias (in other words, extending from the top layer to the base layer) and can be either filled or plated vias, while other vias 103j can be filled or plated blind vias (i.e. terminating at an internal layer. While not showing, certain vias 103j can be buried vias (initiate and terminate between layers that are neither the top layer nor the base layer). As shown, contact 106 can be partially embedded/exposed 107 within AME 10, as in the X-Y cutaway in FIG. 6, which is formed by creating a through hole via having portion 603 removed without removing any portion of conductive filled via 604, resulting in partially embedded/exposed contact 107. Similarly, contact pad 105 for side mounting of chip package (e.g., 208, FIG. 2), can be formed using structure 605, removing the structure and thereby forming contact pad 105. In the context of the disclosure, The term “partially embedded”, means that, when the AME with side-mounted components' contacts, are each fully fabricated using the methods disclosed, at least the surface (e.g., 604′) that is most distal to the side facet surface 602 of the printed circuit structures 601 either protrudes 606 out from the side facet surface 602 or is flush 604′ with the surface 602; and at least the bottoms 614, 616 (the surface most proximal the facet surface 602) are surrounded by the DI material 601.

As illustrated, the various contacts 104p, contact pads 105, and connectors 106, and 207n, can be connected to integrated circuits, or chip packages 110, 120q, 130, ESA 140 (FIG. 1), 205q, and 206 (FIG. 2) using integrally printed traces 102i, and 203i. Furthermore, as illustrated with regard to ports 141 and 142 of ESA 140, these ports can be formed as illustrated in FIG. 6 by forming blind via initiating at the base layer and terminating at a subsequent layer above the base layer and below the top layer. Another example of contacts fabricated by the methods described herein using blind vias is illustrated in FIG. 2, by contacts 222, and using buried vias by contact 221.

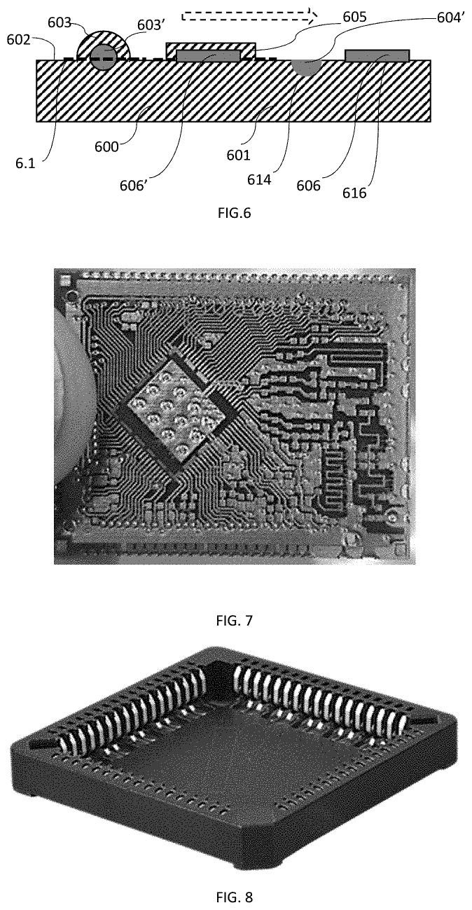

Contact 108 in FIG. 1, can form a portion of socket 109, configured to operably couple (in other words, maintain electric communication with), complimentary surface 209 and groove 210 of AME 20 illustrated in FIG. 2 effectively forming a tongue-in-groove coupling. AME 20 can form another socket 209′ having expose trace 211′ configured to couple to another AME, having a complementary surface, for example protruding socket portion 501 of AME 500, having plurality of contact pads 502k. As illustrated in FIG. 5, the coupling can be continuous, creating a 180° angle and ostensibly a continuous surface, or in 90° degrees. However, the complementary socket surface can be configured to operably connect adjacent AME circuit at any angle desired, thus further enabling the shrinking of the packaging. Moreover, by varying the angles between adjacent AME's (essentially, folding AMEs onto each-other), it is possible to shorten contacts between components on top surfaces, as well as add additional orthogonally separated and isolated ESAs for multiple path communication.

Conversely, the side-mounted contacts fabricated using the AM methods described herein and shown in FIG. 7, can be used in an exemplary implementation, to operably couple, the AME with side-mounted components' contacts, to a socket installed in another AME circuit, for example in a plastic leaded chip carrier (PLCC). The AMEs having side-mounted contacts fabricated using the methods provided herein can likewise be operable to be engaged in other types of sockets, for example in ceramic leaded chip carrier (CLCC).

The term “comprising” and its derivatives, as used herein, are intended to be open ended terms that specify the presence of the stated features, elements, components, groups, integers, and/or steps, but do not exclude the presence of other unstated features, elements, components, groups, integers and/or steps. The foregoing also applies to words having similar meanings such as the terms, “including”, “having” and their derivatives.

All ranges disclosed herein are inclusive of the endpoints, and the endpoints are independently combinable with each other. “Combination” is inclusive of blends, mixtures, alloys, reaction products, and the like. The terms “a”, “an” and “the” herein do not denote a limitation of quantity, and are to be construed to cover both the singular and the plural, unless otherwise indicated herein or clearly contradicted by context. The suffix “(s)” as used herein is intended to include both the singular and the plural of the term that it modifies, thereby including one or more of that term (e.g., the print head(s) includes one or more print head). Reference throughout the specification to “one exemplary implementation”, “another exemplary implementation”, “an exemplary implementation”, “certain configurations”, and so forth, when present, means that a particular element (e.g., feature, structure, step and/or characteristic) described in connection with the exemplary implementation is included in at least one exemplary implementation described herein, and may or may not be present in other configurations. In addition, it is to be understood that the described elements may be combined in any suitable manner in the various configurations. Furthermore, the terms “first,” “second,” and the like, herein do not denote any order, quantity, or importance, but rather are used to denote one element from another.

In relation to systems, methods, AME circuits and programs, the term “operable” means the system and/or the device and/or the program, or a certain element or step is fully functional sized, adapted and calibrated, comprises elements for, and meets applicable operability requirements to perform a recited function when activated, coupled, implemented, effected, realized or when an executable program is executed by at least one processor associated with the system and/or the device. In relation to systems and AME circuits, the term “operable” means the system and/or the circuit is fully functional and calibrated, comprises logic for, and meets applicable operability requirements to perform a recited function when executed by at least one processor.

Likewise, the term “about” means that amounts, sizes, formulations, parameters, and other quantities and characteristics are not and need not be exact, but may be approximate and/or larger or smaller, as desired, reflecting tolerances, conversion factors, rounding off, measurement error and the like, and other factors known to those of skill in the art. In general, an amount, size, formulation, parameter or other quantity or characteristic is “about” or “approximate” whether or not expressly stated to be such.

Accordingly and in an implementation, provided herein is an additively manufactured electronic (AME) circuit (interchangeable with AME) comprising, or containing at least one of a printed circuit board (PCB), flexible printed circuit (FPC), and a high-density interconnect PCB (HDIPCB), the AME circuit comprising at least one of: a side-mounted component, and a plurality of side-mounted contacts, wherein (i) the plurality of side-mounted contacts are partially embedded in the AME circuit, (ii) the component side-mounted to the AME circuit, is a chip package without the singulated IC corresponding to that side-mounted package, wherein (iii) the chip package is at least one of: a Quad Flat Pack (QFP) package, a Thin Small Outline Package (TSOP), a Small Outline Integrated Circuit (SOIC) package, a Small Outline J-Lead (SOJ) package, a Plastic Leaded Chip Carrier (PLCC) package, a Wafer Level Chip Scale Package (WLCSP), a Mold Array Process-Ball Grid Array (MAPBGA) package, a Quad Flat No-Lead (QFN) package, and a Land Grid Array (LGA) package, (iv) the plurality of side-mounted contacts are at least one of a partially embedded filled through-hole via, a partially embedded blind via, and a partially embedded buried via, (v) are orthogonally separated, wherein (vi) the orthogonally separated contact are operable as orthogonally isolated elements for an electrically small antenna (ESA), (vii) the plurality of side-mounted contacts are operable as a portion of a socket, wherein (viii) the socket forms a tongue-in-groove coupling to at least one of another AME circuit, wherein (ix) at least one of the side contact forms a contact for at least one of the tongue and the groove, and wherein (x) the plurality of side-mounted contacts are adapted sized and configured to match the contacts of a socket installed in another AME.

In another implementation, provided herein is a method for additively manufactured electronic (AME) circuit comprising at least one of a printed circuit board (PCB), flexible printed circuit (FPC), and a high-density interconnect PCB (HDIPCB), the AME circuit comprising at least one of: a side-mounted component, and a plurality of side-mounted contacts using additive manufacturing, the method comprising: providing an ink jet printing system having: a first print head adapted to dispense a dielectric ink; a second print head adapted to dispense a conductive ink; a conveyor, operably coupled to the first and second print heads, configured to convey a substrate to each print heads; and a computer aided manufacturing (“CAM”) module, in communication with each of the first, and second print heads, the CAM further comprising a central processing module (CPM) including at least one processor, in communication with a non-transitory computer readable storage medium configured to store instructions that, when executed by the at least one processor cause the CAM to control the ink-jet printing system, by carrying out steps that comprise: receiving a 3D visualization file representing the AME circuit each comprising at least one side-mounted component; and generating a file library having a plurality of files, each file representing a substantially 2D layer for printing the AME circuit each comprising at least one side-mounted component, and a metafile representing at least the printing order; providing the dielectric inkjet ink composition, and the conductive inkjet ink composition; using the CAM module, obtaining the first layer file; using the first print head, forming the pattern corresponding to the dielectric inkjet ink; curing the pattern corresponding to the dielectric inkjet ink; using the second print head, forming the pattern corresponding to the conductive ink, the pattern further corresponding to the substantially 2D layer for printing of the AME circuit each comprising at least one side-mounted component; sintering the pattern corresponding to the conductive inkjet ink; using the CAM module, obtaining from the library a subsequent file representative of a subsequent layer for printing the AME circuit each comprising at least one side-mounted component; the subsequent file comprising printing instructions for a pattern representative of at least one of: the dielectric ink, and the conductive ink; repeating the steps of: using the first print head, forming the pattern corresponding to the dielectric ink, to the step of using the CAM module, obtaining from the 2D file library the subsequent, substantially 2D layer, wherein upon printing the final layer, the AME circuit each comprising at least one side-mounted component comprises a plurality of conductive side mounted contacts operable to mount at least one component; and optionally coupling at least one component to the plurality of printed side contacts, wherein (xi) the plurality of side-mounted contacts are partially embedded in the AME circuit, wherein (xii) the at least one component side-mounted is a chip package that is at least one of: a Quad Flat Pack (QFP) package, a Thin Small Outline Package (TSOP), a Small Outline Integrated Circuit (SOIC) package, a Small Outline J-Lead (SOJ) package, a Plastic Leaded Chip Carrier (PLCC) package, a Wafer Level Chip Scale Package (WLCSP), a Mold Array Process-Ball Grid Array (MAPBGA) package, a Quad Flat No-Lead (QFN) package, and a Land Grid Array (LGA) package, (xiii) the plurality of side-mounted contacts are at least one of a partially embedded filled through-hole via, a partially embedded blind via, and a partially embedded buried via, wherein (xiv) the plurality of side-mounted contacts are orthogonally separated, (xv) the orthogonally separated contact are operable as orthogonally isolated elements for an electrically small antenna (ESA), wherein (xvi) the plurality of side-mounted contacts are operable as a portion of a socket, (xvii), forming a tongue-in-groove coupling to at least one another AME circuit, wherein (xviii) at least one of the side contact forms a contact for at least one of the tongue and the groove, the method further comprising (xix) using the first print head, printing a pattern corresponding to a via, the pattern corresponding to the via extending peripherally from the facet the AME circuit; curing the pattern corresponding to the via; using the second print head, printing a pattern corresponding to a conductive portion of the via; sintering the pattern corresponding to the conductive portion of the via; and removing at least a portion of a vertical portion of the cured dielectric pattern extending peripherally, thereby exposing a portion of the conductive ink, wherein the step of removing at least a portion of a vertical portion of the cured dielectric pattern extending peripherally, comprises using at least one of: a laser applicator, a lathe, a knife, and a resin removing means, thereby exposing the conductive contact, and wherein (xx) the step of removing further comprises shaping the embedded contact.

Although the foregoing disclosure for 3D printing at least one AME, comprising side-mounted contacts, traces, ports and the like, using inkjet printing based on converted 3D visualization CAD/CAM data packages has been described in terms of some exemplary configurations, other exemplary configurations will be apparent to those of ordinary skill in the art from the disclosure herein. Moreover, the described exemplary configurations have been presented by way of example only, and are not intended to limit the scope of the inventions. Indeed, the novel methods, programs, libraries and systems described herein may be embodied in a variety of other forms without departing from the spirit thereof. Accordingly, other combinations, omissions, substitutions and modifications will be apparent to the skilled artisan in view of the disclosure herein.

1. An additively manufactured electronic (AME) circuit comprising at least one of a printed circuit board (PCB), flexible printed circuit (FPC), and a high-density interconnect PCB (HDIPCB), the AME circuit comprising at least one of: a side-mounted component, and a plurality of side-mounted contacts.

2. The AME circuit of claim 1, wherein the plurality of side-mounted contacts are partially embedded in the AME circuit.

3. The AME circuit of claim 2, wherein the component side-mounted to the AME circuit, is a chip package.

4. The AME circuit of claim 3, wherein the chip package is at least one of: a Quad Flat Pack (QFP) package, a Thin Small Outline Package (TSOP), a Small Outline Integrated Circuit (SOIC) package, a Small Outline J-Lead (SOJ) package, a Plastic Leaded Chip Carrier (PLCC) package, a Wafer Level Chip Scale Package (WLCSP), a Mold Array Process-Ball Grid Array (MAPBGA) package, a Quad Flat No-Lead (QFN) package, and a Land Grid Array (LGA) package.

5. The AME circuit of claim 4, wherein the plurality of side-mounted contacts are at least one of a partially embedded filled through-hole via, a partially embedded blind via, and a partially embedded buried via.

6. The AME circuit of claim 5, wherein the plurality of side-mounted contacts are orthogonally separated.

7. The AME circuit of claim 6, wherein the orthogonally separated contact are operable as orthogonally isolated elements for an electrically small antenna (ESA).

8. The AME circuit of claim 5, wherein the plurality of side-mounted contacts are operable as a portion of a socket.

9. The AME circuit of claim 8, wherein the socket forms a tongue-in-groove coupling to at least one of another AME circuit.

10. The AME circuit of claim 9, wherein at least one of the side contact forms a contact for at least one of the tongue and the groove.

11. The AME circuit of claim 6, wherein the plurality of side-mounted contacts are adapted sized and configured to match the contacts of a socket installed in another AME.

12. A method for additively manufactured electronic (AME) circuit comprising at least one of a printed circuit board (PCB), flexible printed circuit (FPC), and a high-density interconnect PCB (HDIPCB), the AME circuit comprising at least one of: a side-mounted component, and a plurality of side-mounted contacts using additive manufacturing, the method comprising:
a. providing an ink jet printing system having:
i. a first print head adapted to dispense a dielectric ink;
ii. a second print head adapted to dispense a conductive ink;
iii. a conveyor, operably coupled to the first and second print heads, configured to convey a substrate to each print heads; and
iv. a computer aided manufacturing (“CAM”) module, in communication with each of the first, and second print heads, the CAM further comprising a central processing module (CPM) including at least one processor, in communication with a non-transitory computer readable storage medium configured to store instructions that, when executed by the at least one processor cause the CAM to control the ink-jet printing system, by carrying out steps that comprise: receiving a 3D visualization file representing the AME circuit each comprising at least one side-mounted component; and generating a file library having a plurality of files, each file representing a substantially 2D layer for printing the AME circuit each comprising at least one side-mounted component, and a metafile representing at least the printing order;
b. providing the dielectric inkjet ink composition, and the conductive inkjet ink composition;
c. using the CAM module, obtaining the first layer file;
d. using the first print head, forming the pattern corresponding to the dielectric inkjet ink;
e. curing the pattern corresponding to the dielectric inkjet ink;
f. using the second print head, forming the pattern corresponding to the conductive ink, the pattern further corresponding to the substantially 2D layer for printing of the AME circuit each comprising at least one side-mounted component;
g. sintering the pattern corresponding to the conductive inkjet ink;
h. using the CAM module, obtaining from the library a subsequent file representative of a subsequent layer for printing the AME circuit each comprising at least one side-mounted component; the subsequent file comprising printing instructions for a pattern representative of at least one of: the dielectric ink, and the conductive ink;
i. repeating the steps of: using the first print head, forming the pattern corresponding to the dielectric ink, to the step of using the CAM module, obtaining from the 2D file library the subsequent, substantially 2D layer, wherein upon printing the final layer, the AME circuit each comprising at least one side-mounted component comprises a plurality of conductive side mounted contacts operable to mount at least one component; and
j. optionally coupling at least one component to the plurality of printed side contacts.

13. The method of claim 12, wherein the plurality of side-mounted contacts are partially embedded in the AME circuit.

14. The method of claim 12, wherein the at least one component side-mounted is a chip package that is at least one of: a Quad Flat Pack (QFP) package, a Thin Small Outline Package (TSOP), a Small Outline Integrated Circuit (SOIC) package, a Small Outline J-Lead (SOJ) package, a Plastic Leaded Chip Carrier (PLCC) package, a Wafer Level Chip Scale Package (WLCSP), a Mold Array Process-Ball Grid Array (MAPBGA) package, a Quad Flat No-Lead (QFN) package, and a Land Grid Array (LGA) package.

15. The method of claim 14, wherein the plurality of side-mounted contacts are at least one of a partially embedded filled through-hole via, a partially embedded blind via, and a partially embedded buried via.

16. The method of claim 15, wherein the plurality of side-mounted contacts are orthogonally separated.

17. The method of claim 16, wherein the orthogonally separated contact are operable as orthogonally isolated elements for an electrically small antenna (ESA).

18. The method of claim 12, wherein the plurality of side-mounted contacts are operable as a portion of a socket.

19. The method of claim 18, wherein the socket forms a tongue-in-groove coupling to at least one another AME circuit.

20. The method of claim 19, wherein at least one of the side contact forms a contact for at least one of the tongue and the groove.

21. The method of claim 12, further comprising:
a. using the first print head, printing a pattern corresponding to a via, the pattern corresponding to the via extending peripherally from the facet the AME circuit;
b. curing the pattern corresponding to the via;
c. using the second print head, printing a pattern corresponding to a conductive portion of the via;
d. sintering the pattern corresponding to the conductive portion of the via; and
e. removing at least a portion of a vertical portion of the cured dielectric pattern extending peripherally, thereby exposing a portion of the conductive ink,
wherein the step of removing at least a portion of a vertical portion of the cured dielectric pattern extending peripherally, comprises using at least one of: a laser applicator, a lathe, a knife, and a resin removing means, thereby exposing the conductive contact.

22. The method of claim 21, wherein the step of removing further comprises shaping the embedded contact.

23. An additively manufactured electronic (AME) circuit comprising at least one of a printed circuit board (PCB), flexible printed circuit (FPC), and a high-density interconnect PCB (HDIPCB), fabricated by any one of claims 12-22.
